(19) United States
(12) Patent Application Publication
(10) Pub. No.: US 2007/0194435 A1
(43) Pub. Date: Aug. 23, 2007

(54) SEMICONDUCTOR DEVICE AND METHOD OF MANUFACTURING THE SAME

(76) Inventor: Yoshihiko SHIMANUKI, Nanae (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/618,159

(22) Filed: Dec. 29, 2006

(30) Foreign Application Priority Data
Feb. 22, 2006 (JP) 2006-45727

(51) Int. Cl. H01L 23/12

(52) U.S. Cl. 257/700

(57) ABSTRACT

Peeling of the core material in the wiring substrate of a semiconductor device is suppressed.

The multi-chip substrate is divided so that the foldout direction of fiber and the dividing direction of a substrate in each of first core material of two sheets of a multi-chip substrate may accomplish an acute angle, and fiber is exposed to the end face formed of this division. When the foldout direction of each fiber of the first core material of two sheets and the extending direction of the end face accomplish an acute angle, fiber woven into first core material can be made fine. Exposure of the portion of resin comparatively weak to stress can be lessened. As a result, peeling of resin in a cutting plane can be suppressed. Since the foldout direction and the dividing direction of fiber are an acute angle, progress of peeling can be suppressed.

### CROSS-REFERENCE TO RELATED APPLICATION

The present application claims priority from Japanese patent application No. 2006-45727 filed on Feb. 22, 2006, the content of which is hereby incorporated by reference into this application.

1. Field of the Invention

The present invention relates to a semiconductor device and its assembly, and particularly relates to an effective technology in the application to the semiconductor device which has a wiring substrate.

2. Description of the Background Art

The multi-chip substrate cut from the substrate base material so that the foldout direction of glass fiber and the extending direction of a cutting plane might accomplish an acute angle or an obtuse angle is prepared. And in the dicing step after a batch molding, there is technology which does dicing of the multi-chip substrate so that the foldout direction and cutting direction of the glass fiber of a multi-chip substrate may accomplish an acute angle or an obtuse angle (for example, refer to Patent Reference 1).

[Patent Reference 1] Japanese Unexamined Patent Publication No. 2003-124395 (FIG. 4)

### SUMMARY OF THE INVENTION

As a product (semiconductor device) which mounts a semiconductor chip on a wiring substrate, BGA (Ball Grid Array), CSP (Chip Size Package), etc. are known, for example. When individually separating a wiring substrate by a dicing blade by the assembling process of such a semiconductor device and a dicing blade is run right-angled or in parallel to the foldout direction of the fiber woven into the core material of a wiring substrate, since the cutting stress of a dicing blade progresses easily toward the center of a core material via a fiber from a cutting plane (end face), a crack is formed in a core material or the resin which forms a core material peels (crack).

Then, it becomes possible to suppress that cutting stress progresses toward a center from the cutting plane of a core material by running a dicing blade acutely to the foldout direction of the fiber of a core material as shown in the Patent Reference 1 (Japanese Unexamined Patent Publication No. 2003-124395).

Here, a wiring layer (wiring pattern) is formed in the core material which wove the fiber into the resin material, and the structure of a wiring substrate is formed. As shown in the Patent Reference 1, and also wiring substrate 16 of a comparative example of FIG. 17 and FIG. 18, when core part (core material) 16a comprises one layer (monolayer), what has the relatively thick fiber itself woven in in the resin material is used. There are also many amounts of resin 16c with which it fills up between fibers in connection with this relatively.

Therefore, since there are many amounts of peeling resin 16c relatively when peeling of resin 16c occurs even if it has suppressed progress of cutting stress by running a dicing blade acutely to the foldout direction of fiber 16b of core part 16a, it is a problem that it is easy to become a poor product.

Resin 16c deteriorates easily by thermal contraction, such as a temperature cycle. Hereby, since the adhesion force of fiber 16b, and resin 16c which deteriorated declines, peeling (crack) generates it. When the fiber itself is relatively thick at this time, it is a problem that the amount of peeling of resin 16c generated due to lowering of the adhesion force also becomes large relatively.

Since wiring substrate 16 used is also thinly formed in connection with the thickness reduction of a semiconductor device, the thickness of core part 16a is also thin. Therefore, when wiring substrate 16 is individually separated by a dicing blade, since the strength of the core part itself is low, it is a problem that it is easy to generate a crack in a thickness direction.

A purpose of the present invention is to offer the technology which can suppress peeling of the core material in the wiring substrate of a semiconductor device.

A purpose of the present invention is to offer the technology which can improve the temperature cycle property of a semiconductor device.

The above-described and the other purposes and novel features of the present invention will become apparent from the description herein and accompanying drawings.

Of the inventions disclosed in the present application, typical ones will next be summarized briefly.

That is, in the present invention, the foldout direction of a fiber and the extending direction of the end face which a fiber exposes have accomplished the acute angle in each core material of two sheets of a wiring substrate.

The present invention has a step which exposes a fiber to the end face formed by this division by dividing a multi-chip substrate so that the foldout direction of the fiber in each of the core material of two sheets of a multi-chip substrate and a dividing direction may accomplish an acute angle. The foldout direction of each fiber of the core material of two sheets in a multi-chip substrate and the extending direction of an end face accomplish an acute angle.

Advantages achieved by some of the most typical aspects of the invention disclosed in the present application will be briefly described below.

By making the core material in a wiring substrate into two layers (two or more layers), the fiber woven into a core material can be made fine, and a length of one side of the grid of the resin divided by the fiber can be shortened. Therefore, by doing dicing of the wiring substrate so that the foldout direction of each fiber of the core material of two layers and a dividing direction may accomplish an acute angle, the diagonal line of the grid of resin can be shortened and the portion of resin comparatively weak to stress can be lessened. As a result, while being able to suppress peeling of resin, the foldout direction and dividing direction of a fiber are an acute angle, and progress of peeling can be suppressed. Hereby, the generation with a faulty product can be reduced.

### BRIEF DESCRIPTION OF THE DRAWINGS

FIG. 1 is a plan view penetrating a sealing body and in which showing an example of the structure of the semiconductor device of Embodiment 1 of the present invention;

FIG. 2 is a cross-sectional view showing the structure of the semiconductor device shown in FIG. 1;

FIG. 3 is an enlarged partial sectional view showing the structure of the section A shown in FIG. 2;

FIG. 4 is an enlarged partial sectional view showing an example of the structure of the wiring substrate included in the semiconductor device shown in FIG. 1;

FIG. 5 is a plan view showing an example of the foldout direction of the fiber in the core material of the wiring substrate shown in FIG. 4;

FIG. 6 is an enlarged partial sectional view showing the structure of the wiring substrate of the modification included in the semiconductor device shown in FIG. 1;

FIG. 7 is a plan view showing an example of the foldout direction of the fiber in one core material of the wiring substrate shown in FIG. 6;

FIG. 8 is an enlarged partial sectional view showing the structure of the wiring substrate of other modifications included in the semiconductor device shown in FIG. 1;

FIG. 9 is a manufacture process-flow picture showing an example of the assembly to the resin molding in the assembly of the semiconductor device shown in FIG. 1;

FIG. 10 is a manufacture process-flow picture showing an example of the assembly after the resin molding in the assembly of the semiconductor device shown in FIG. 1;

FIG. 11 is a manufacture process-flow picture showing the modification of the assembly after the resin molding in the assembly of the semiconductor device shown in FIG. 1;

FIG. 12 is a plan view showing an example in the state where the traveling direction of the dicing blade at the time of the individual separation of the assembly shown in FIG. 10 and the foldout direction of a fiber accomplish an acute angle;

FIG. 13 is a plan view showing an example in the state where the traveling direction of the dicing blade at the time of the individual separation of the assembly shown in FIG. 10 and the foldout direction of a fiber accomplish a right angle or parallel;

FIG. 14 is an enlarged partial sectional view showing an example of the structure of the wiring substrate included in the semiconductor device of Embodiment 2 of the present invention;

FIG. 15 is an enlarged partial sectional view showing the structure of the wiring substrate of the modification included in the semiconductor device of Embodiment 2 of the present invention;

FIG. 16 is an enlarged partial sectional view showing the structure of the wiring substrate of other modifications included in the semiconductor device of Embodiment 2 of the present invention; and

FIGS. 17 and 18 are enlarged partial sectional views showing the structure of the wiring substrate of a comparative example.

### DETAILED DESCRIPTION OF THE PREFERRED EMBODIMENTS

In the following embodiments, except the time when especially required, explanation of identical or similar part is not repeated in principle.

In the below-described embodiments, a description will be made after divided into plural sections or in plural embodiments if necessary for convenience sake. These plural sections or embodiments are not independent each other, but in relation such that one is a modification example, details or complementary description of a part or whole of the other one unless otherwise specifically indicated.

In the below-described embodiments, when a reference is made to the number of elements (including the number, value, amount and range), the number is not limited to a specific number but may be equal to or greater than or less than the specific number, unless otherwise specifically indicated or principally apparent that the number is limited to the specific number.

Hereafter, embodiments of the invention are explained in detail based on drawings. In all the drawings for describing the embodiments, members of a like function will be identified by like reference numerals and overlapping descriptions will be omitted.

### Embodiment 1

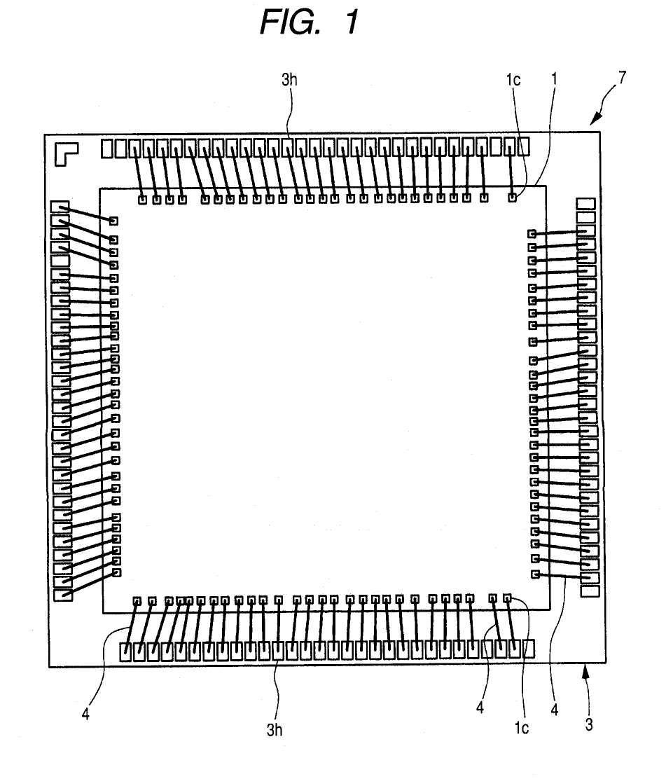

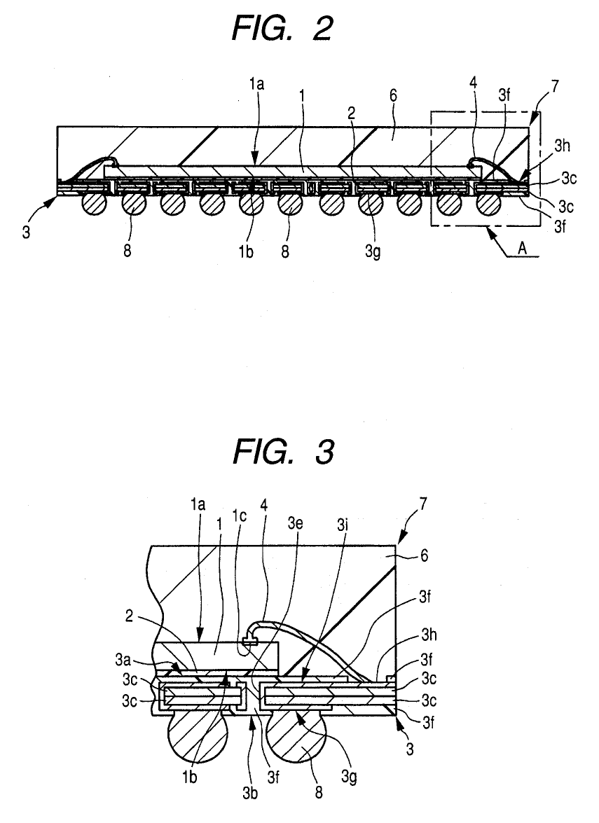

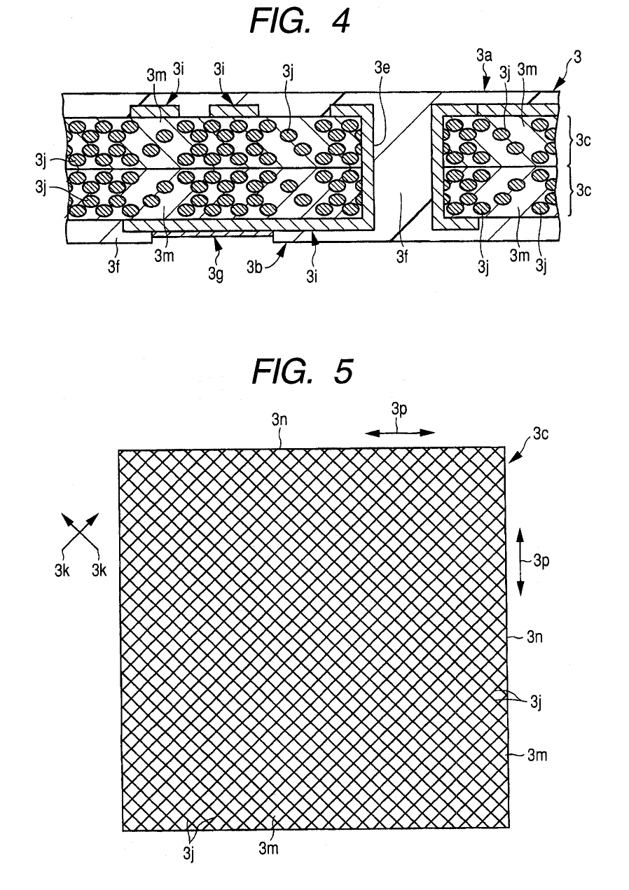

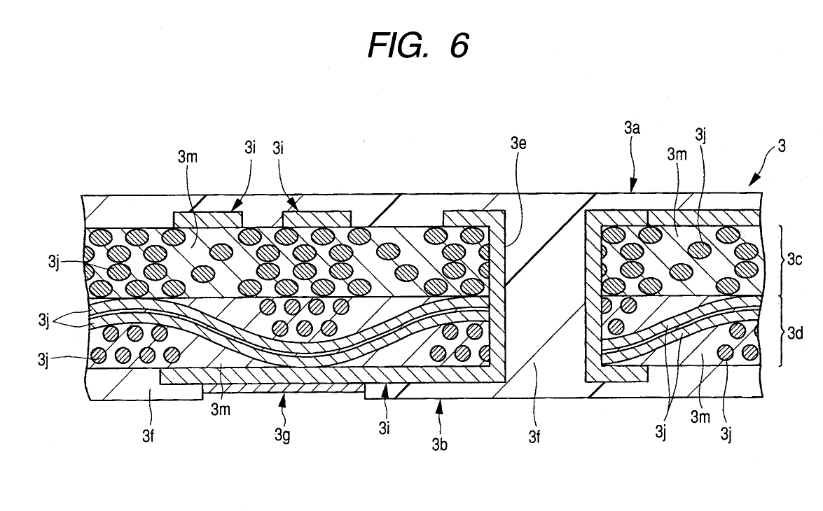

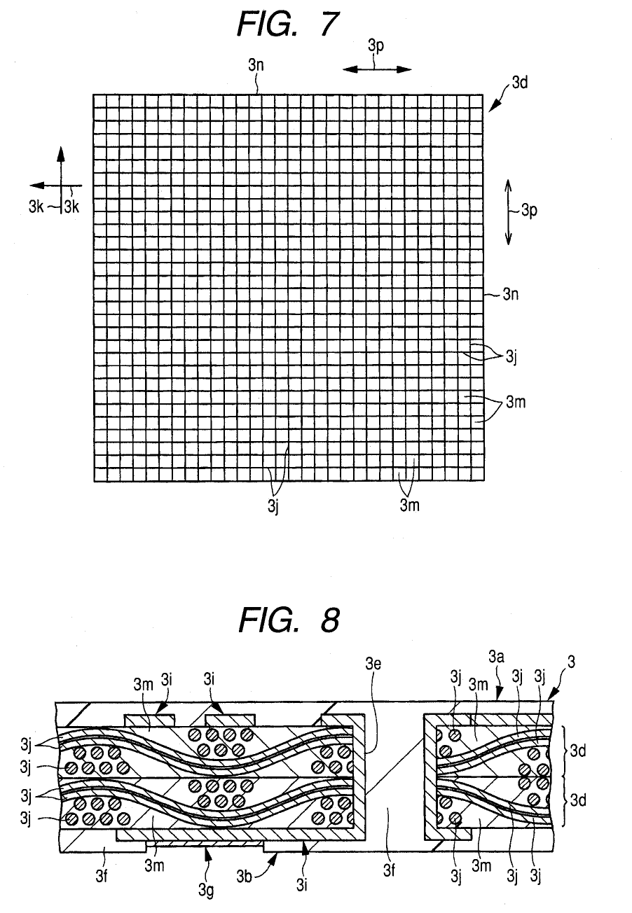

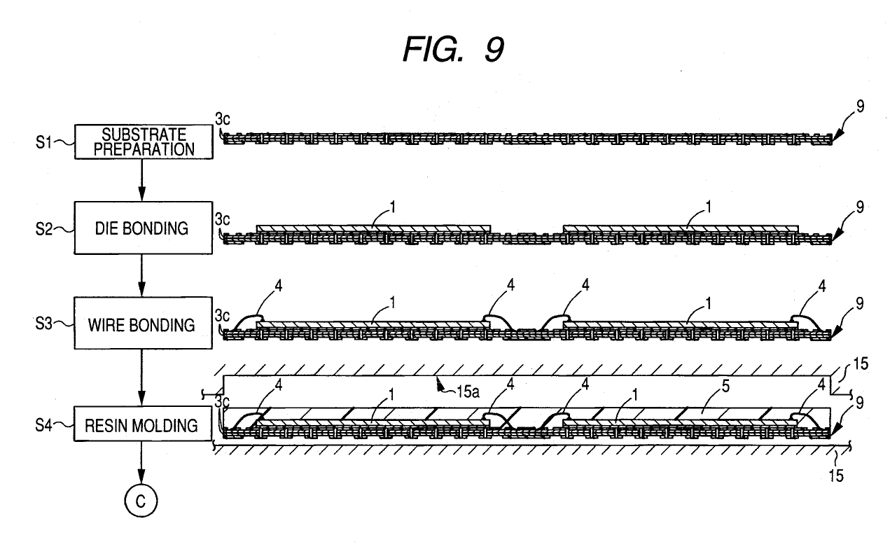

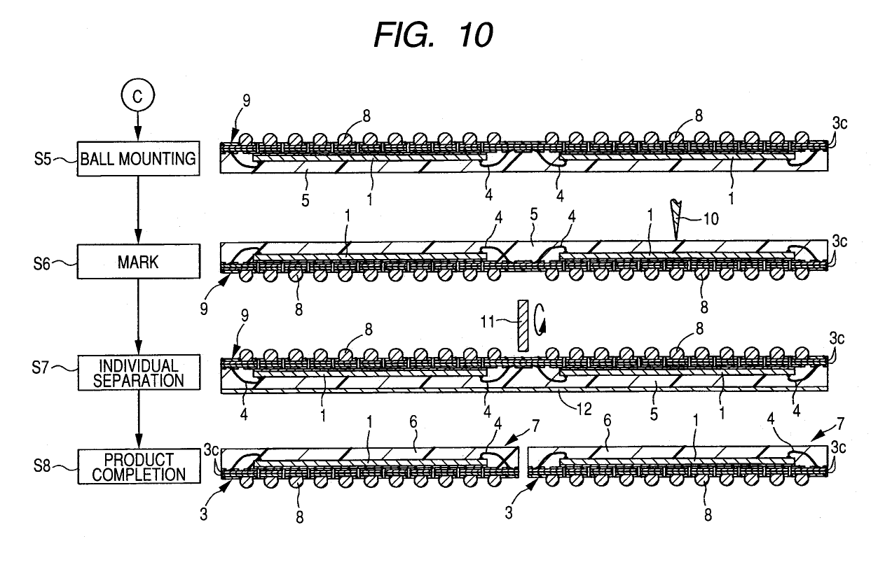

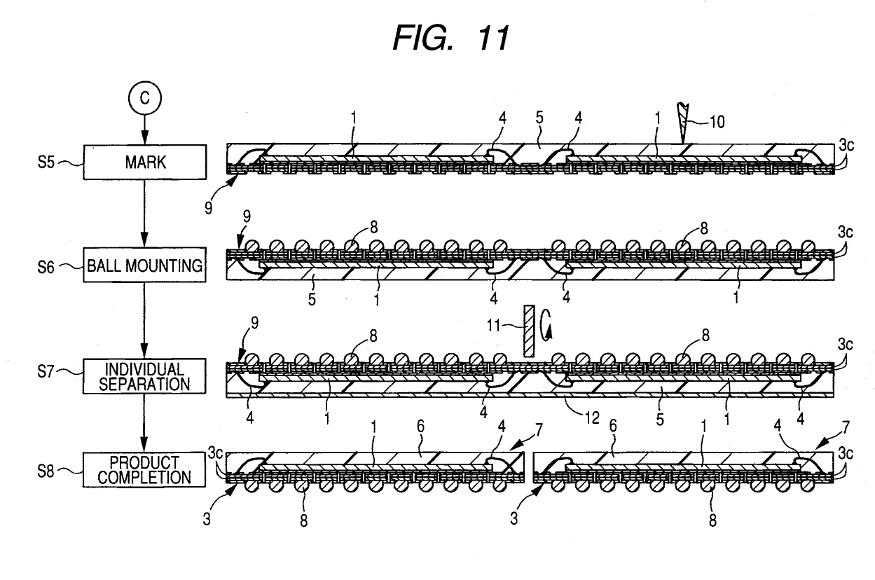

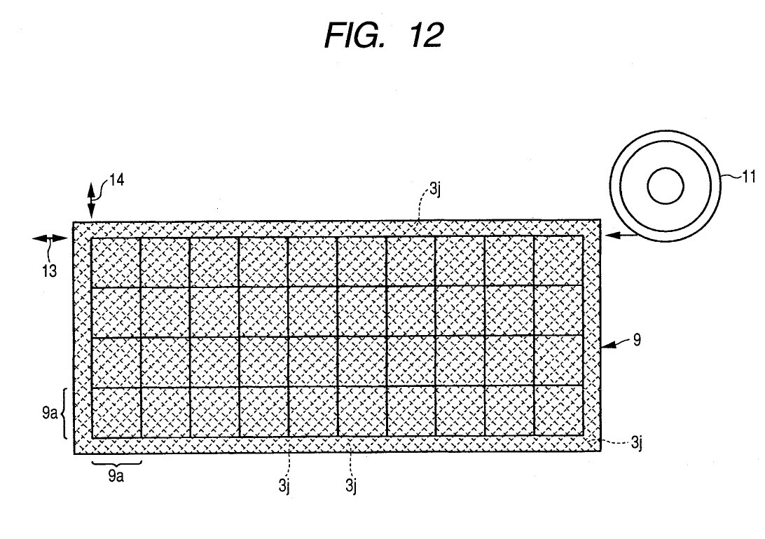

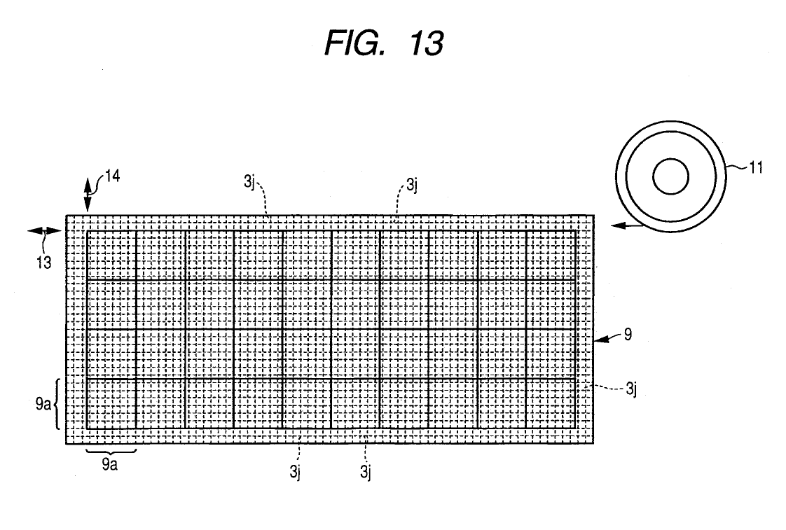

FIG. 1 is a plan view penetrating a sealing body and in which showing an example of the structure of the semiconductor device of Embodiment 1 of the present invention; FIG. 2 is a cross-sectional view showing the structure of the semiconductor device shown in FIG. 1; FIG. 3 is an enlarged partial sectional view showing the structure of the section A shown in FIG. 2; FIG. 4 is an enlarged partial sectional view showing an example of the structure of the wiring substrate included in the semiconductor device shown in FIG. 1; FIG. 5 is a plan view showing an example of the foldout direction of the fiber in the core material of the wiring substrate shown in FIG. 4; FIG. 6 is an enlarged partial sectional view showing the structure of the wiring substrate of the modification included in the semiconductor device shown in FIG. 1; FIG. 7 is a plan view showing an example of the foldout direction of the fiber in one core material of the wiring substrate shown in FIG. 6; FIG. 8 is an enlarged partial sectional view showing the structure of the wiring substrate of other modifications included in the semiconductor device shown in FIG. 1; FIG. 9 is a manufacture process-flow picture showing an example of the assembly to the resin molding in the assembly of the semiconductor device shown in FIG. 1; FIG. 10 is a manufacture process-flow picture showing an example of the assembly after the resin molding; FIG. 11 is a manufacture process-flow picture showing the modification of the assembly after the resin molding in the assembly of the semiconductor device shown in FIG. 1; FIG. 12 is a plan view showing an example in the state where the traveling direction of the dicing blade at the time of the individual separation of the assembly shown in FIG. 10 and the foldout direction of a fiber accomplish an acute angle; and FIG. 13 is a plan view showing an example in the state where the traveling direction of the dicing blade at the time of the individual separation and the foldout direction of a fiber accomplish a right angle or parallel.

The semiconductor device of Embodiment 1 is a small semiconductor package of the resin molded type by which semiconductor chip 1 is mounted on a wiring substrate, it takes up CSP7 as shown in FIG. 1-FIG. 3 as the example, and Embodiment 1 explains it. Solder ball 8 which are a plurality of external terminals is arranged in a lattice manner, and is attached to back surface 3b of a wiring substrate, and CSP7 is a BGA type semiconductor package whose plane size of a semiconductor package is almost equivalent to a semiconductor chip.

When the structure of CSP7 shown in FIG. 1-FIG. 3 is explained, it includes package substrate 3 which is a wiring substrate, semiconductor chip 1 which is mounted in main surface 3a of package substrate 3, and has an integrated circuit, electrically conductive wire 4 which electrically connects pad 1c which is an electrode of semiconductor chip 1, and the electrode for bonding of main surface 3a of package substrate 3, solder ball 8 which was formed on the land of the plurality of back surface 3b of package substrate 3 and which are a plurality of external terminals, and resin body 6.

Semiconductor chip 1 includes silicon etc., for example, and the integrated circuit is formed in the main surface 1a. The plane form in semiconductor chip 1 which intersects the thickness is rectangular shape, and it is a square in Embodiment 1. As shown in FIG. 1, a plurality of pads 1c electrically connected with an integrated circuit are formed in the edge part of main surface 1a. This pad 1c, and electrodes 3h for bonding arranged in the edge part of main surface 3a of package substrate 3 are electrically connected by electrically conductive wire 4, respectively. This wire 4 is a gold wire etc., for example.

As shown in FIG. 3, the back surface 1b adheres to package substrate 3 via adhesives 2, such as a paste agent and a die attach film, and semiconductor chip 1 is mounted in package substrate 3, where main surface 1a is turned up. When adhesives 2 are die attach films, it may be beforehand stuck on the back surface 1b side of semiconductor chip 1.

Resin body 6 is formed in the main surface 3a side of package substrate 3, and does the resin seal of semiconductor chip 1 and a plurality of electrically conductive wires 4, for example while it includes epoxy system resin etc.

For example, it includes solder, such as Pb—Sn, and connects with the second electrode of back surface 3b of package substrate 3, and solder ball 8 which are a plurality of external terminals formed in back surface 3b of package substrate 3 is arranged in a lattice manner.

Package substrate 3 has main surface 3a and back surface 3b opposite to main surface 3a, a plurality of electrodes 3h for bonding (first electrode, bonding lead) formed in the edge part of main surface 3a, and 3g of a plurality of lands (second electrode) formed in back surface 3b and a plurality of through holes 3e which connect a wiring of a main surface side and the wiring of a back surface side. That is, a plurality of electrodes 3h for bonding formed in the edge part of main surface 3a are electrically connected to lands 3g of back surface 3b via through hole 3e which corresponds, respectively.

The plane form in package substrate 3 which intersects the thickness is rectangular shape, and it is a square in Embodiment 1.

Package substrate 3 has a core material which includes first core material (fiber layer) 3c of two sheets with which it has arranged in piles between main surface 3a and back surface 3b, and a plurality of fibers 3j were woven into each by crossing, as shown in FIG. 4 and FIG. 5. As a material of fiber 3j, a glass cloth is used, for example. That is, package substrate 3 pastes together comparatively thin first core material 3c of two sheets, and is formed. The thickness of the core material portion after pasting together first core material 3c of two sheets is about 0.1 mm, for example, and the total thickness of a substrate including solder-resist films 3f which are an insulating film of a back-and-front surface is about 0.2 mm, for example.

What has a size of the fiber included in a core material relatively thick when it forms a package substrate from a core material of one sheet is used. However, when one core material is formed from dividing a core material into two sheets and sticking it like Embodiment 1, the thickness of each first core material 3c becomes thinner to about a half than the case where a package substrate is formed from a core material of one sheet. Therefore, the thing thinner than the case where a package substrate is formed from a core material of one sheet also about the size of fiber 3j included in each first core material 3c is used. When the size of fiber 3j becomes thin, microfabrication also of the foldout can be done and the meshes of a net formed by fiber 3j will also be in a denser state.

Thus, even if the total thickness of the core material itself is almost the same as compared with the case of the package substrate which includes a core material of one sheet by pasting together first core material 3c of a state with dense meshes of a net, the mechanical strength of package substrate 3 can be improved. That is, the thickness reduction of CSP7 is corresponded to.

a plurality of electrodes 3h for bonding formed in the edge part of main surface 3a are electrically connected to lands 3g of back surface 3b via copper wiring 3i, through hole 3e, etc. Solder ball 8 which is an external terminal is connected to this land 3g. The conductor pattern of thin films, such as electrodes 3h for bonding, copper wiring 3i, through hole 3e, and lands 3g, is formed with the copper alloy, for example.

In package substrate 3 included in CSP7 of Embodiment 1, as shown in FIG. 4, first core material 3c of two sheets is stuck. As shown in FIG. 5, as for first core material 3c, the foldout direction 3k of fiber 3j and extending direction (extending direction of the side of package substrate 3) 3p which is end faces 3n (side surface) of package substrate 3 which fiber 3j exposes accomplish an acute angle (or obtuse angle).

Therefore, that which pasted together first core material 3c of two sheets with the same foldout direction 3k of fiber 3j and from which the core material became 2 layer structure by this is adopted as package substrate 3. That is, in each stuck first core material 3c, the foldout direction 3k of fiber 3j and extending direction 3p of end faces 3n have accomplished the acute angle.

As a result, it can suppress that cutting stress progresses toward a center from the cutting plane of a core material. Since first core material 3c of a state with dense meshes of a net is stacked like Embodiment 1 by making into 2 layer structure first core material 3c which is a core material in package substrate 3, progress of peeling (crack) to the thickness direction of a core material can be suppressed. As a result, the generation with a faulty product of CSP7 etc. can be reduced.

Fiber 3j woven into a core material can be made fine by pasting together first core material 3c of two sheets, and making it 2 layer structure so that the foldout direction 3k of fiber 3j and extending direction 3p of end faces 3n may accomplish the same acute angle. Since a foldout of fiber 3j which forms meshes of a net can be formed densely, the pitch between fibers 3j which adjoined can be narrowed. Hereby, a length of one side of the grid of resin 3m divided by fiber 3j can be shortened.

That is, when each foldout direction 3k of fiber 3j and extending direction 3p of end faces 3n of the core material of two layers have accomplished the same acute angle, the diagonal line (distance between fibers 3j which adjoin each other in the end face of package substrate 3) of the grid of resin 3m can be shortened. The exposing portion of resin 3m comparatively weak to stress, or a heat temperature cycle can be lessened. As a result, since the foldout direction 3k of fiber 3j and extending direction 3p of end faces 3n are acute angles while being able to suppress peeling of resin 3m, progress of peeling can be suppressed. Hereby, the generation with a faulty product of CSP7 etc. can be reduced.

Next, the modification of Embodiment 1 is explained.

FIG. 6 shows the modification of package substrate 3, and a core material is a thing of 2 layer structure which pastes together first core material (fiber layer) 3c and second core materials 3d (fiber layer). As shown in FIG. 7, as for second core materials 3d, the foldout direction 3k of fiber 3j and extending direction (extending direction of the side of package substrate 3) 3p which is end faces 3n of package substrate 3 which fiber 3j exposes accomplish a right angle or parallel.

That is, in package substrate 3 of the modification shown in FIG. 6, the foldout direction 3k of fiber 3j of first core material 3c differs from the foldout direction 3k of fiber 3j of second core materials 3d. In simple, then one side, as shown in FIG. 5, the foldout direction 3k of fiber 3j and extending direction 3p of end faces 3n accomplish an acute angle. On the other hand, as shown in FIG. 7, the foldout direction 3k of fiber 3j and extending direction 3p of end faces 3n have accomplished a right angle or parallel.

Since resin 3m deteriorates easily by thermal contraction, such as a temperature cycle, as described above, the adhesion force of fiber 3j and resin 3m declines. The problem on which resin 3m between fibers 3j which exposes to the end face (cutting plane) of package substrate 3 peels occurs. As shown in FIG. 4, when the foldout direction 3k of fiber 3j and extending direction 3p of end faces 3n of first core material (fiber layer) 3c have accomplished the same acute angle, it can suppress that cutting stress progresses toward a center from the cutting plane of a core material. However, as shown in FIG. 5, when the foldout direction 3k of fiber 3j has accomplished the acute angle to extending direction 3p of end face 3 of package substrate 3, the distance between adjacent fibers 3j becomes wider (longer) than the case where the foldout direction 3k of fiber 3j and extending direction 3p of end faces 3n accomplish a right angle or parallel as shown in FIG. 7. Therefore, when resin 3m peels by thermal contraction, such as a temperature cycle, and it drops out of package substrate 3, the amount of resin 3m with which the structure of being shown in FIG. 5 drops out rather than the structure shown in FIG. 7 becomes large.

On the other hand, by pasting together first core material 3c and second core materials 3d with which the foldout directions 3k of fiber 3j differed as shown in FIG. 6, and making it the core material of 2 layer structure (then simply expressing, the foldout direction 3k of fiber 3j and extending direction 3p of end faces 3n in one of core materials (fiber layer) accomplish a right angle or parallel between two core materials), fiber 3j of a plurality of directions crosses, and the area (amount of resin 3m) of the portion of resin 3m exposed to a cutting plane (end faces 3n) can be reduced rather than the structure shown in FIG. 4.

When the problem of thermal contraction, such as a temperature cycle, is more serious than the problem of the cutting stress of a dicing blade, and it has structure as shown in FIG. 6, rather than the structure shown in FIG. 4, the temperature cycle property of package substrate 3 can be improved, and the reliability of CSP7 can be increased. Progress of peeling is suppressed and the generation with a faulty product of CSP7 etc. can be reduced.

When first core material 3c and second core materials 3d with which the foldout directions 3k of fiber 3j differed are pasted together in package substrate 3 of the modification of FIG. 6, first core material 3c of FIG. 5 with which the foldout direction 3k of fiber 3j and extending direction 3p of end faces 3n accomplish an acute angle is arranged at the main surface 3a side (above), and second core materials 3d of FIG. 7 with which the foldout direction 3k of fiber 3j and extending direction 3p of end faces 3n accomplish a right angle or parallel are arranged at the back surface 3b side (below).

This is because, when temperature cycle property is taken into consideration, big stress is given for the more distant place from semiconductor chip 1 (product made from silicon), the thermal stress to which the side of lower (back surface 3b side) second core materials 3d (fiber layer) is applied is larger than an upside (main surface 3a side, a semiconductor chip mounting side), therefore, the side which has arranged second core materials 3d with which the foldout direction 3k of fiber 3j and extending direction 3p of end faces 3n accomplish a right angle or parallel to the down side can suppress exposure of the portion of resin 3m weak to temperature cycle property.

That is, by arranging first core material 3c with which the foldout direction 3k of fiber 3j and extending direction 3p of end faces 3n accomplish an acute angle at the main surface 3a side (above), and arranging second core materials 3d with which the foldout direction 3k of fiber 3j and extending direction 3p of end faces 3n accomplish a right angle or parallel at the back surface 3b side (below), the temperature cycle property of package substrate 3 can be improved further, and the reliability of CSP7 can be increased more. Progress of peeling is also suppressed and the generation with a faulty product of CSP7 etc. can be reduced further.

When the core material of two sheets is pasted together and the core material of 2 layer structure is formed in the modification shown in FIG. 8, second core materials 3d which are shown in FIG. 7 and with which the foldout direction 3k of fiber 3j and extending direction 3p of end faces 3n accomplish a right angle or parallel in two sheets were adopted. Also according to this structure, progress of peeling can be suppressed and the generation with a faulty product of CSP7 etc. can be reduced.

Next, the manufacturing method of CSP7 of Embodiment 1 is explained using the manufacture process-flow picture shown in FIG. 9-FIG. 11.

First, the substrate preparation shown in Step S1 of FIG. 9 is made. Here, multi-chip substrate 9 by which device region 9a which is a region which forms CSP7 has been arranged in a plurality of blocks as shown in FIG. 12 is prepared. In each device region 9a, the core material of two sheets woven in by a plurality of fibers 3j crossing is arranged in piles between main surface 3a and back surface 3b.

The case where multi-chip substrate 9 (refer to FIG. 12) to which first core material 3c of two sheets with which the foldout direction 3k of fiber 3j shown in FIG. 5 and extending direction 3p of end faces 3n of package substrate 3 at the time of being cut (extending direction of the side of package substrate 3) accomplish an acute angle here was stuck as shown in FIG. 4 is used is taken up as an example, and is explained.

Then, die bonding shown in Step S2 is performed, and semiconductor chip 1 is adhered via adhesives 2 shown in FIG. 3 on multi-chip substrate 9. Semiconductor chip 1 is mounted inside 3h of electrode row for bonding of the edge part of each device region 9a in the case.

Then, wire bonding shown in Step S3 is performed. Here, as shown in FIG. 3, electrodes 3h for bonding of device region 9a of multi-chip substrate 9 corresponding to this are electrically connected with pad 1c of main surface 1a of semiconductor chip 1 with electrically conductive wires 4, such as a gold wire.

Then, the resin molding shown in Step S4 is performed. Here, on multi-chip substrate 9, the resin seal of a plurality of semiconductor chip 1 and a plurality of wires 4 is covered collectively and done by one cavity 16a of resin-molding metallic mold 15, and batch molded body 5 is formed by this. The resin for sealing which forms batch molded body 5 is a thermosetting epoxy resin etc., for example.

Then, ball mounting shown in Step S5 of FIG. 10 is performed, and as shown in FIG. 3, solder ball 8 is connected to each land 3g of back surface 3b of package substrate 3.

Then, the mark shown in Step S6 is performed. Here, marking 10 is performed by the laser marking method etc., and a mark is given to batch molded body 5. Marking 10 may be performed by the ink marking method etc., for example.

Then, individual separation shown in Step S7 is performed. Here, dicing tape 12 is stuck on the front surface of batch molded body 5, dicing blade 11 cuts in the state where it fixed with dicing tape 12, and it individually separates to each CSP7.

Dicing cuts and divides multi-chip substrate 9 so that the foldout direction 3k of fiber 3j and traveling direction 13 of a blade of the X direction (dividing direction) in each of first core material 3c of two sheets of multi-chip substrate 9 may accomplish an acute angle, and the foldout direction 3k of fiber 3j and traveling direction 14 of a blade of the Y direction (dividing direction) may accomplish an acute angle, respectively, as shown in FIG. 12 in the case, and fiber 3j is exposed to end faces 3n shown in the FIG. 5 formed of this division.

Since first core material 3c of two sheets is stuck in multi-chip substrate 9 shown in FIG. 12 so that the foldout direction 3k of fiber 3j shown in FIG. 5 and extending direction 3p of end faces 3n at the time of being cut may accomplish an acute angle, by running each of traveling direction 13 of the blade of the X direction, and traveling direction 14 of the blade of the Y direction dicing blade 11, the foldout direction 3k of fiber 3j and extending direction 3p of end faces 3n at the time of being cut accomplish an acute angle.

The individual separation is performed, and as shown in Step S8, the assembly of CSP7 is completed and it becomes product completion.

In the manufacturing method of the semiconductor device of Embodiment 1, first core material 3c of two sheets is pasted together so that the foldout direction 3k of fiber 3j and extending direction 3p of end faces 3n may accomplish the same acute angle, and dicing of the multi-chip substrate 9 from which the core material became 2 layer structure by this is done. Fiber 3j woven into a core material can be made fine by this, and the pitch between adjacent fibers 3j can be narrowed further. Since the pitch between adjacent fibers 3j can be narrowed, a length of one side of the grid of resin 3m divided by fiber 3j can be shortened.

Therefore, when each foldout direction 3k of fiber 3j and extending direction 3p of end faces 3n of the core material of two layers have accomplished the same acute angle, the diagonal line of the grid of resin 3m can be shortened, and the exposing portion of resin 3m comparatively weak to stress can be lessened. As a result, while being able to suppress peeling of resin 3m, the foldout direction 3k of fiber 3j and extending direction 3p of end faces 3n are acute angles, and progress of peeling can be suppressed. Hereby, the generation with a faulty product of CSP7 etc. can be reduced.

Since a core material is stacked by making into 2 layer structure first core material 3c which is a core material in package substrate 3, progress of peeling to the thickness direction of a core material can be suppressed. As a result, the generation with a faulty product of CSP7 etc. can be reduced.

Next, FIG. 11 is a manufacture process-flow picture showing the modification of the assembly after a resin molding.

The modification shown in FIG. 11 performs ball mounting, after marking.

At the step of ball mounting, after applying solder to lands 3g of package substrate 3, solder ball 8 is formed by reflow treatment. For this reason, also in the step of ball mounting, the problem that package substrate 3 warps further by this reflow treatment occurs. At the step of a mark, although marking is performed by the laser marking method etc., after package substrate 3 has warped, since it becomes difficult to irradiate laser at right angles to the front surface of batch molded body 5, poor marking that a mark is not given to the front surface of batch molded body 5 occurs.

So, in the modification shown in FIG. 11, before performing reflow treatment at the time of solder ball 8 formation which is one of the factors in which package substrate 3 warps, the step of a mark is performed previously. Hereby, poor marking can be suppressed.

Next, multi-chip substrate 9 of the modification shown in FIG. 13 has second core materials 3d with which the foldout direction 3k of fiber 3j shown in FIG. 7 and extending direction 3p of end faces 3n cut accomplish a right angle or parallel. For example, it is set as the core material of 2 layer structure combining 3d of this second core material, and first core material 3c of multi-chip substrate 9 shown in FIG. 12. The form of first core material 3c and the form of second core materials 3d combine in plan view by doing dicing of this substrate at the time of the individual separation in the case of an assembly. So, the area (amount of resin 3m) of the portion of resin 3m which fiber 3j of a plurality of directions crosses, and is exposed to a cutting plane can be reduced.

Hereby, the temperature cycle property of package substrate 3 can be improved, and the reliability of CSP7 can be increased. Progress of peeling is suppressed and the generation with a faulty product of CSP7 etc. can be reduced.

### Embodiment 2

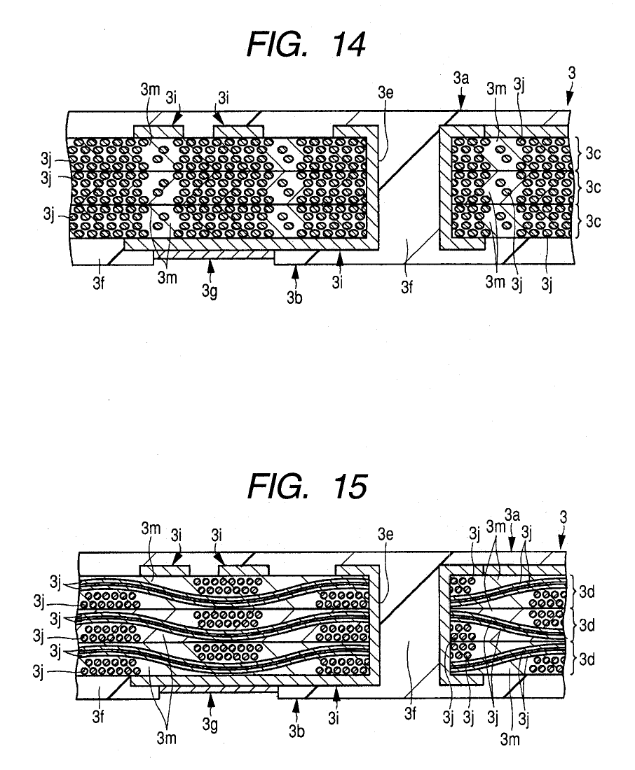

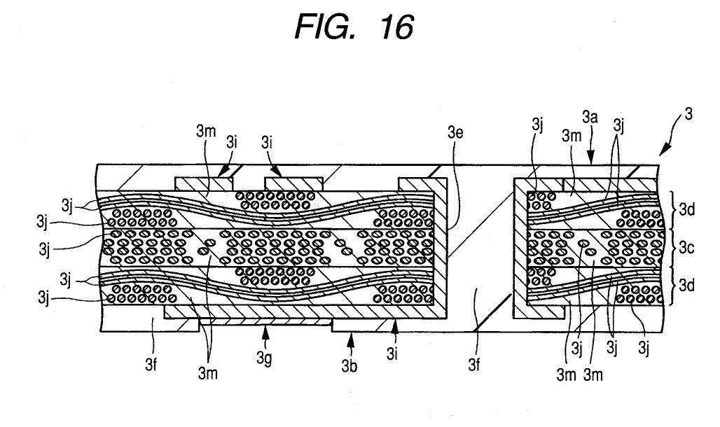

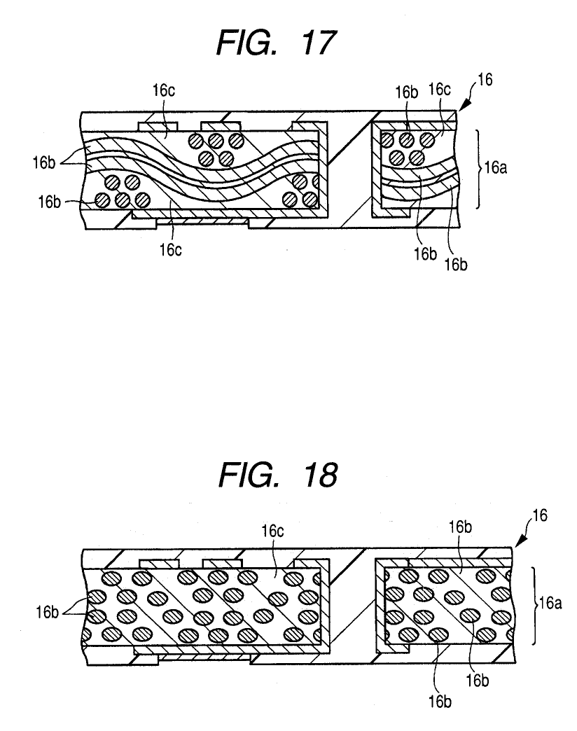

FIG. 14 is an enlarged partial sectional view showing an example of the structure of the wiring substrate included in the semiconductor device of Embodiment 2 of the present invention. FIG. 15 is an enlarged partial sectional view showing the structure of the wiring substrate of the modification included in the semiconductor device of Embodiment 2 of the present invention, and FIG. 16 is an enlarged partial sectional view showing the structure of the wiring substrate of other modifications included in the semiconductor device of Embodiment 2 of the present invention.

FIG. 14-FIG. 16 show the structure of package substrate 3 of Embodiment 2. The example of package substrate 3 which pasted the core material of three sheets together and was used as the core material of 3 layer structure is shown. First, in package substrate 3 shown in FIG. 14, three first core materials 3c as shown in FIG. 5 are stuck. The foldout direction 3k of fiber 3j and extending direction 3p of end faces 3n cut accomplish an acute angle, respectively.

Therefore, what pasted together first core material 3c whose foldout direction 3k of fiber 3j is the same in three sheets, and made the core material 3 layer structure is adopted as package substrate 3. That is, in each first core material 3c, the foldout direction 3k of fiber 3j and extending direction 3p of end faces 3n have accomplished the acute angle.

Thus, since a core material is stacked by making into 3 layer structure first core material 3c which is a core material in package substrate 3, progress of peeling to the thickness direction of a core material can be suppressed further. As a result, the generation with a faulty product of CSP7 etc. can be reduced.

Since first core material 3c of the up-and-down layer of the first core materials 3c of three layers adjusts expansion/contraction of a core material, a warp of package substrate 3 can be suppressed.

In package substrate 3 of the modification shown in FIG. 15, 3d of three second core materials as shown in FIG. 7 are stuck. The foldout direction 3k of fiber 3j and extending direction 3p of end faces 3n cut have accomplished a right angle or parallel, respectively. Also in this case, progress of peeling to the thickness direction of a core material can be suppressed, and a warp of package substrate 3 can be suppressed further.

As for package substrate 3 of the modification shown in FIG. 16, the core material with which the foldout direction 3k of fiber 3j and extending direction 3p of end faces 3n to which fiber 3j exposes have accomplished the respectively same first angle to the top layer and an undermost layer among the core materials of three layers is arranged. The core material which accomplishes a different second angle from the first angle between the top layer and an undermost layer is arranged. As an example, the case where the first angle is right-angled or parallel, and the second angle is an acute angle is illustrated.

That is, in the modification shown in FIG. 16, second core materials 3d with which the foldout direction 3k of fiber 3j and extending direction 3p of end faces 3n have accomplished a right angle or parallel (first angle) in the up-and-down layer among the core materials of three layers and which are shown in FIG. 7 are arranged. First core material 3c with which the foldout direction 3k of fiber 3j and extending direction 3p of end faces 3n have accomplished the acute angle (second angle) to the intermediate layer and which is shown in FIG. 5 is arranged.

Thus, since the core material of an up-and-down layer adjusts expansion/contraction of the whole core material by arranging the core material into which the angle which the foldout direction 3k of fiber 3j and extending direction 3p of end faces 3n accomplish was changed by the up-and-down layer and the intermediate layer, a warp of package substrate 3 can be suppressed further.

In the foregoing, the present invention accomplished by the present inventors is concretely explained based on above embodiments, but the present invention is not limited by the above embodiments, but variations and modifications may be made, of course, in various ways in the limit that does not deviate from the gist of the invention.

For example, although the Embodiment 1 and 2 explained the case where a core material was two layers or three layers, in package substrate 3, as long as a plurality of two or more-layer layers are put and stuck together and formed, the number of the core materials may be any. However, when a warp of package substrate 3 is taken into consideration, it is preferred that the number of the core materials is odd. In the front surface of fiber 3j, irregularity may be formed by mechanical processing or chemical processing. Hereby, the adhesion of fiber 3j and resin 3m can be improved. Hereby, since peeling of resin 3m can be suppressed, the reliability of CSP7 can be increased.

The present invention is suitable for an electronic device with a wiring substrate.

What is claimed is:

1. A semiconductor device, comprising:
a wiring substrate which has a main surface, a back surface opposite to the main surface, a plurality of first electrodes formed in the main surface, a plurality of second electrodes formed in the back surface, and a core material of two sheets which has been arranged in piles between the main surface and the back surface, and was woven into each by a plurality of fibers crossing;
a semiconductor chip mounted over the main surface of the wiring substrate;
a plurality of wires which electrically connect a plurality of electrodes of the semiconductor chip, and the first electrodes formed in the main surface of the wiring substrate, respectively;
a resin body which seals the semiconductor chip and the wires; and
a plurality of external terminals formed over the second electrodes;
wherein in each of the core material of two sheets, a foldout direction of the fiber and an extending direction of an end face of the wiring substrate which the fiber exposes accomplish an acute angle.

2. A semiconductor device, comprising:
a wiring substrate which has a main surface, a back surface opposite to the main surface, a plurality of first electrodes formed in the main surface, a plurality of second electrodes formed in the back surface, and a core material of two sheets which has been arranged in piles between the main surface and the back surface, and was woven into each by a plurality of fibers crossing;
a semiconductor chip mounted over the main surface of the wiring substrate;
a plurality of wires which electrically connect a plurality of electrodes of the semiconductor chip, and the first electrodes formed in the main surface of the wiring substrate, respectively;
a resin body which seals the semiconductor chip and the wires; and
a plurality of external terminals formed over the second electrodes;
wherein
as for one side, a foldout direction of the fiber and an extending direction of an end face which the fiber exposes accomplish an acute angle among the core materials of two sheets; and
in another side, a foldout direction of the fiber and an extending direction of an end face of the wiring substrate which the fiber exposes accomplish a right angle or parallel.

3. A semiconductor device according to claim 2, wherein
among the core materials of two sheets, a core material with which a foldout direction of the fiber and an extending direction of the end face accomplish an acute angle is arranged at the main surface side, and a core material with which a foldout direction of the fiber and an extending direction of the end face accomplish a right angle or parallel is arranged at the back surface side.

4. A semiconductor device, comprising:
a wiring substrate which has a main surface, a back surface opposite to the main surface, a plurality of first electrodes formed in the main surface, a plurality of second electrodes formed in the back surface, and a wiring substrate which has a core material of three or more sheets which has been arranged in piles between the main surface and the back surface, and was woven into each by a plurality of fibers crossing;
a semiconductor chip mounted over the main surface of the wiring substrate;
a plurality of wires which electrically connect a plurality of electrodes of the semiconductor chip, and the first electrodes formed in the main surface of the wiring substrate, respectively;
a resin body which seals the semiconductor chip and the wires; and
a plurality of external terminals formed over the second electrodes;
wherein in each of the core material of three or more sheets, a foldout direction of the fiber and an extending direction of an end face of the wiring substrate which the fiber exposes have accomplished the same angle.

5. A semiconductor device according to claim 4, wherein
each foldout direction of the fiber and extending direction of the end face of the core material of the three or more sheets have accomplished the same acute angle.

6. A semiconductor device according to claim 4, wherein
each foldout direction of the fiber and extending direction of the end face of the core material of the three or more sheets have accomplished a right angle or parallel.

7. A semiconductor device, comprising:
a wiring substrate which has a main surface, a back surface opposite to the main surface, a plurality of first electrodes formed in the main surface, a plurality of second electrodes formed in the back surface, a core material of odd sheets which has been arranged in piles between the main surface and the back surface, and was woven into each by a plurality of fibers crossing;
a semiconductor chip mounted over the main surface of the wiring substrate;
a plurality of wires which electrically connect a plurality of electrodes of the semiconductor chip, and the first electrodes formed in the main surface of the wiring substrate, respectively;
a resin body which seals the semiconductor chip and the wires; and
a plurality of external terminals formed over the second electrodes;
wherein
a core material with which a foldout direction of the fiber and an extending direction of an end face which the fiber exposes have accomplished the respectively same first angle is arranged to a top layer and an undermost layer among the core materials of odd sheets; and
a core material which accomplishes a different second angle from the first angle is arranged between the top layer and the undermost layer.

8. A semiconductor device according to claim 7, wherein
three sheets of the core material are arranged, the first angle is right-angled or parallel, and the second angle is an acute angle.

9. A method of manufacturing a semiconductor device, comprising the steps of:
(a) preparing a multi-chip substrate which has a main surface, a back surface opposite to the main surface, a plurality of first electrodes formed in the main surface, a plurality of second electrodes formed in the back surface, and a core material of two sheets which has been arranged in piles and woven into each by a plurality of fibers crossing between the main surface and the back surface;
(b) mounting a semiconductor chip over the main surface of the multi-chip substrate;
(c) electrically connecting with a wire a plurality of electrodes of the semiconductor chip, and the first electrodes formed in the main surface of the multi-chip substrate, respectively;
(d) sealing the semiconductor chip and a plurality of wires; and
(e) exposing the fiber to an end face formed by a division by dividing the multi-chip substrate so that each foldout direction of the fiber and dividing direction of the core material of two sheets of the multi-chip substrate may accomplish an acute angle;
wherein each foldout direction of the fiber and extending direction of the end face of the core material of two sheets in the multi-chip substrate accomplish an acute angle.

10. A method of manufacturing a semiconductor device, comprising the steps of:
(a) preparing a multi-chip substrate which has a main surface, a back surface opposite to the main surface, a plurality of first electrodes formed in the main surface, a plurality of second electrodes formed in the back surface, and a core material of two sheets which has been arranged in piles and woven into each by a plurality of fibers crossing between the main surface and the back surface;
(b) mounting a semiconductor chip over the main surface of the multi-chip substrate;
(c) electrically connecting with a wire a plurality of electrodes of the semiconductor chip, and the first electrodes formed in the main surface of the multi-chip substrate, respectively;
(d) sealing the semiconductor chip and a plurality of wires; and
(e) exposing the fiber to an end face formed by a division, by dividing so that a foldout direction and dividing direction of the fiber may accomplish an acute angle as to one core material, and by dividing the multi-chip substrate so that a foldout direction and dividing direction of the fiber may accomplish a right angle or parallel as to a core material of another side among the core materials of two sheets of the multi-chip substrate;
wherein as for one core material, a foldout direction of the fiber and an extending direction of the end face accomplish an acute angle among the core materials of two sheets of the multi-chip substrate, and as for a core material of another side, a foldout direction of the fiber and an extending direction of the end face accomplish a right angle or parallel.

11. A method of manufacturing a semiconductor device according to claim 10, wherein
among the core materials of two sheets, a core material with which a foldout direction of the fiber and an extending direction of the end face accomplish an acute angle is arranged at the main surface side, and a core material with which a foldout direction of the fiber and an extending direction of the end face accomplish a right angle or parallel is arranged at the back surface side.

12. A method of manufacturing a semiconductor device, comprising the steps of:
(a) preparing a multi-chip substrate which has a main surface, a back surface opposite to the main surface, a plurality of first electrodes formed in the main surface, a plurality of second electrodes formed in the back surface, and a core material of three or more sheets which has been arranged in piles and woven into each by a plurality of fibers crossing between the main surface and the back surface;
(b) mounting a semiconductor chip over the main surface of the multi-chip substrate;
(c) electrically connecting with a wire a plurality of electrodes of the semiconductor chip, and the first electrodes formed in the main surface of the multi-chip substrate, respectively;
(d) sealing the semiconductor chip and a plurality of wires; and
(e) exposing the fiber to an end face formed by a division by dividing the multi-chip substrate so that a foldout direction of each of the fiber of the core material of three or more sheets of the multi-chip substrate and a dividing direction may accomplish the same angle,
wherein each foldout direction of the fiber and extending direction of the end face of the core material of three or more sheets in the multi-chip substrate accomplish the same angle.

13. A method of manufacturing a semiconductor device according to claim 12, wherein
a foldout direction of each of the fiber of the core material of three or more sheets and an extending direction of the end face accomplish the same acute angle.

14. A method of manufacturing a semiconductor device according to claim 12, wherein
a foldout direction of each of the fiber of the core material of three or more sheets and an extending direction of the end face accomplish a right angle or parallel.
